(19) United States
(12) Patent Application Publication
(10) Pub. No.: US 2025/0267828 A1
(43) Pub. Date: Aug. 21, 2025

(54) DISPLAY DEVICE, HEAT DISSIPATION PLATE AND METHOD OF FABRICATING DISPLAY DEVICE

(71) Applicant: LG Display Co., Ltd., Seoul (KR)

(72) Inventors: SoJung PARK, Paju-si (KR); Kelly Sooyeun SONG, Paju-si (KR); Hyesun SON, Paju-si (KR)

(73) Assignee: LG Display Co., Ltd., Seoul (KR)

(21) Appl. No.: 18/943,444

(22) Filed: Nov. 11, 2024

(30) Foreign Application Priority Data
Feb. 21, 2024 (KR) 10-2024-0024998

(51) Int. Cl. H05K 7/20; B32B 5/02; B32B 5/26; C25D 5/54; C25D 7/00

(52) U.S. Cl. CPC H05K 7/20963; B32B 5/02; B32B 5/26; C25D 5/54; C25D 7/00; B32B 2260/023; B32B 2260/046; B32B 2262/106; B32B 2264/105; B32B 2457/20

(57) ABSTRACT

Embodiments relate to a display device, a heat dissipation plate, and a method of fabricating the display device. The display device includes a display panel and a heat dissipation plate disposed under the display panel. The heat dissipation plate includes a plurality of carbon fibers arranged in one direction and at least one metal particle. The metal particle is provided on a surface of at least one first carbon fiber among the plurality of carbon fibers and in contact with at least one second carbon fiber adjacent to the at least one first carbon fiber. According to embodiments, heat dissipation efficiency of the display device may be improved.

### CROSS REFERENCE TO RELATED APPLICATION

This application claims priority from Korean Patent Application No. 10-2024-0024998, filed on Feb. 21, 2024, which is hereby incorporated by reference for all purposes as if fully set forth herein.

### BACKGROUND

### Technical Field

Embodiments relate to a display device, a heat dissipation plate, and a method of fabricating the display device.

### Discussion of the Related Art

In response to technological advances, display devices that display images are becoming slimmer and improving in performance. To achieve high performance, display devices require more circuits, devices, and other components therein. With more components, display devices may generate more heat when operating.

As display devices become thinner, heat generated during the operation thereof more directly affects the components of the display device, thereby causing abnormalities such as malfunctions and failures.

Therefore, when a display device is running, it is necessary to quickly dissipate the heat generated inside the display device.

### SUMMARY

Accordingly, embodiments of the present disclosure are directed to a display device, a heat dissipation plate, and a method of fabricating the display device that substantially obviate one or more of the problems due to limitations and disadvantages of the related art.

An aspect of the present disclosure is to provide a display device, a heat dissipation plate, and a method of fabricating a display device able to improve heat dissipation efficiency.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a display panel; and a heat dissipation plate disposed under the display panel and including a plurality of carbon fibers arranged in one direction and at least one metal particle, wherein the metal particle is provided on a surface of at least one first carbon fiber among the plurality of carbon fibers and in contact with at least one second carbon fiber adjacent to the at least one first carbon fiber.

In another aspect, a heat dissipation plate comprises: a first carbon fiber layer including a plurality of carbon fibers arranged in one direction; a second carbon fiber layer located over the first carbon fiber layer, and including carbon fibers arranged in the direction in which the carbon fibers included in the first carbon fiber layer are arranged; a first metal particle disposed in the first carbon fiber layer, disposed on a surface of at least one first carbon fiber included in the first carbon fiber layer, and being in contact with at least one second carbon fiber included in the first carbon fiber layer and adjacent to the at least one first carbon fiber, and a second metal particle disposed in the second carbon fiber layer, disposed on a surface of at least one first carbon fiber included in the second carbon fiber layer, and being in contact with at least one second carbon fiber included in the second carbon fiber layer and adjacent to the at least one first carbon fiber.

In another aspect a method of manufacturing a display device comprises: electroplating metal on a plurality of first carbon fibers arranged in one direction and located on a single plane; pressing the plurality of electroplated first carbon fibers; arranging a plurality of electroplated second carbon fibers over the plurality of first carbon fibers, the second carbon fibers being arranged in the direction in which the plurality of first carbon fibers are arranged; pressing the plurality of first carbon fibers and the plurality of second carbon fibers; and attaching the plurality of pressed first carbon fibers and the plurality of pressed second carbon fibers to a back side of a back plate.

According to embodiments, in the display device, the heat dissipation plate, and the method of fabricating a display device, heat dissipation efficiency may be improved.

According to embodiments, in the display device, the heat dissipation plate, and the method of fabricating a display device, the lifetime and reliability of the display device may be improved by improving the heat dissipation efficiency of the display device, thereby realizing the effect of low power consumption.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 illustrates an example of a cross-sectional structure of a display device according to embodiments;

FIG. 2 illustrates another example of a cross-sectional structure of the display device according to embodiments;

FIG. 3 illustrates an example of a 3D structure and a planar structure of the heat dissipation plate shown in FIG. 2;

FIG. 4 illustrates another example of a 3D structure and a planar structure of the heat dissipation plate shown in FIG. 2;

FIG. 5 illustrates an example of a cross-sectional structure of the heat dissipation plate shown in FIG. 4;

FIG. 6 illustrates an example of a cross-sectional structure of the heat dissipation plate shown in FIG. 2;

FIG. 7 illustrates another example of a 3D structure and a planar structure of the heat dissipation plate shown in FIG. 2;

FIG. 8 illustrates an example of a cross-sectional structure of the heat dissipation plate shown in FIG. 7;

FIG. 9A illustrates an example of a method of fabricating the heat dissipation plate shown in FIGS. 4 and 5; and

FIG. 9B illustrates an example of a method of fabricating the heat dissipation plate shown in FIGS. 7 and 8.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, a variety of embodiments will be described in detail with reference to the accompanying drawings.

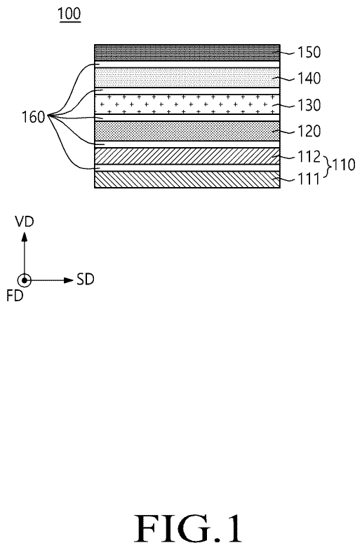

FIG. 1 illustrates an example of a cross-sectional structure of a display device according to embodiments.

Referring to FIG. 1, a display device 100 may include a support plate 110, a back plate 120, a display panel 130, a polarizer 140, a cover glass 150, and adhesive layers 160.

A first direction FD is one direction in a plane on which the support plate 110, the back plate 120, the display panel 130, the polarizer 140, the cover glass 150, or one of the adhesive layers 160 is located. A second direction SD is a direction perpendicular to the first direction FD in the same plane as the above-described plane. A third direction VD is a direction perpendicular to the above-described plane, i.e., the third direction VD is perpendicular to both the first direction FD and the second direction SD.

The support plate 110 may support the display device 100. The support plate 110 may include a first support plate 111 and a second support plate 112, without being limited thereto. As an example, the support plate 110 may include one single support plate or three or more support plates.

As an example, the support plate 110 may be formed of metal. However, the support plate 110 is not limited thereto, and may be formed of plastic. For example, at least one of the first support plate 111 and the second support plate 112 may include polyimide (PI). Embodiments are not limited thereto. As an example, the support plate 110 may be formed of other inorganic or organic materials, such as glass, semiconductor, rubber, etc. As an example, the first support plate 111 and the second support plate 112 may include the same material or different materials.

The back plate 120 may be disposed over the support plate 110. The back plate 120 may maintain the rigidity of the display panel 130 and reduce or prevent debris from adhering to the bottom of the display panel 130

The back plate 120 may be formed of a highly rigid material, such as plastic or metal, to maintain the rigidity of the display panel 130, without being limited thereto. As an example, the back plate 120 may be omitted depending on the design.

The display panel 130 may be disposed over the back plate 120. The display panel 130 may be a layer in which a plurality of subpixels are provided. Transistors or the like for driving the plurality of subpixels are provided inside the display panel 130. As an example, the display panel 130 may be, but is not limited to, an organic light-emitting display (OLED) panel. As another example, the display panel 130 may be a liquid crystal display (LCD) panel, a light-emitting display (LED) panel, a micro-LED panel, etc.

The polarizer 140 may be disposed over the display panel 130. The polarizer 140 may reduce or prevent external light from being reflected inside the display device 100, thereby improving the reflection visibility of the display device 100. The polarizer 140 may be provided as a film having a polarizing function. As an example, the polarizer 140 may be omitted depending on the design.

The cover glass 150 may be disposed over the polarizer 140. The cover glass 150 may protect the elements provided inside the display panel 130. The cover glass 150 may be formed of glass or plastic, without being limited thereto. The cover glass 150 may be transparent.

The adhesive layers 160 may be disposed between the first support plate 111 and the second support plate 112, between the support plate 110 and the back plate 120, between the back plate 120 and the display panel 130, between the display panel 130 and the polarizer 140, and between the polarizer 140 and the cover glass 150, respectively.

The adhesive layers 160 may bond the respective layers of the display device 100 together. For example, the adhesive layers 160 may include, but are not limited to, an optically clear adhesive (OCA) or a pressure sensitive adhesive (PSA). The adhesive layers 160 may be cured by a thermal curing process or an optical curing process without being limited thereto.

The support plate 110 may include a material that is relatively rigid compared to the other layers to support the display device 100. The support plate 110 may also include a material with a high heat dissipation efficiency to better dissipate heat generated by the display device 100 to the outside of the display device 100. In an example, the support plate 110 may include stainless steel to increase rigidity

However, if the support plate 110 includes a material having high rigidity, such as stainless steel, the weight of the support plate 110 will increase, thereby making it difficult to lighten the display device 100.

Therefore, it is desirable that the support plate 110 is formed of a material that is relatively lightweight while being highly heat dissipating.

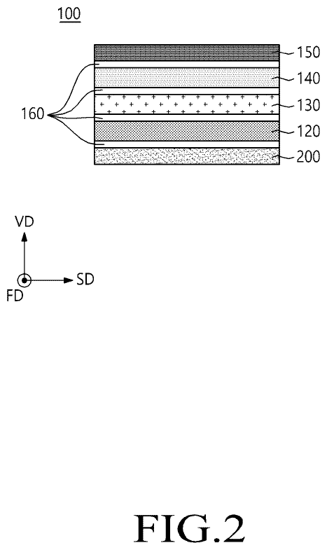

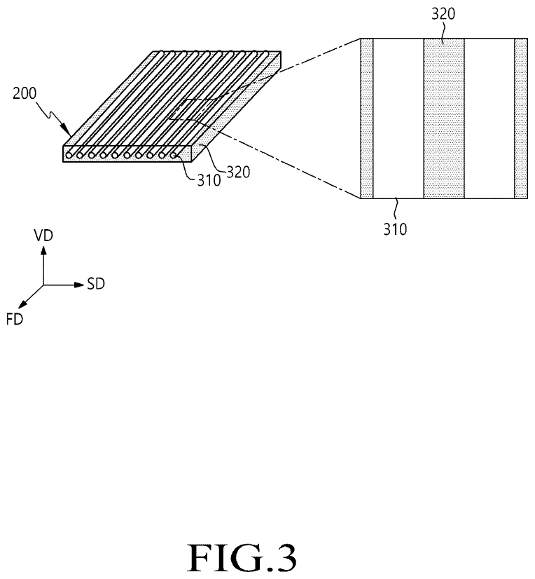

FIG. 2 illustrates another example of a cross-sectional structure of the display device according to embodiments, and FIG. 3 illustrates an example of a 3D structure and a planar structure of the heat dissipation plate shown in FIG. 2.

The display device shown in FIG. 2 is the same as the display device shown in FIG. 1 except that a heat dissipation plate 200 is included in place of the support plate 110, and therefore repetitive description thereof is omitted or briefly given.

Referring to FIGS. 2 and 3, the display device 100 may include a heat dissipation plate 200.

The heat dissipation plate 200 may be located under the back plate 120, and may be bonded to the back surface of the back plate 120 using the adhesive layer 160.

As an example, the heat dissipation plate 200 may include a plurality of carbon fibers 310 and resin 320.

The plurality of carbon fibers 310 may be arranged in one direction or a unidirectional direction UD. For ease of description, an example in which the plurality of carbon fibers 310 are arranged in the first direction FD is described below. As another example, the plurality of carbon fibers 310 may be arranged in more than one direction, without being limited thereto.

As an example, the carbon fibers 310 may refer to fibers each containing at least 92% carbon in the yarn. As another example, the carbon fibers 310 may refer to fibers each containing at least 60%, 70%, 80% carbon in the yarn, without being limited thereto.

The carbon fibers 310 may be, but are not necessarily limited to, poly-acrylonitrile (PAN) carbon fibers or pitch-based carbon fibers.

In FIG. 3, all of the carbon fibers 310 are shown as disposed on the same plane, but the carbon fibers 310 are not necessarily limited thereto. The carbon fibers 310 may be disposed on different planes, or may be stacked in two or more layers.

The resin 320 may include an epoxy-based resin or a urethane-based resin.

The resin 320 may surround the carbon fibers 310 arranged in one direction. Specifically, the resin 320 may be disposed between the carbon fibers 310. The resin 320 may be disposed between the carbon fibers 310 to maintain the shape of the carbon fibers 310 arranged in one direction so that the arrangement of the carbon fibers 310 is not disturbed. As an example, the resin 320 may fully or partially surround the carbon fibers 310. As an example, the resin 320 may expose a portion of the carbon fibers 310, or some of the carbon fibers 310. As an example, ends of the carbon fibers 310 may be exposed by the resin 320 at one side or both sides of the resin 320 in the one direction, without being limited thereto. As an example, ends of the carbon fibers 310 in the one direction may be also surrounded by the resin 320.

The heat dissipation plate 200 described with reference to FIGS. 2 and 3 includes a lighter material, such as a polymeric material, than the support plate 110. Therefore, the heat dissipation plate 200 may be lighter than the support plate 110.

In addition, since all of the carbon fibers 310 are arranged in one direction, the carbon fibers 310 may have superior heat transfer capability in one direction, thereby having a high heat dissipation efficiency.

However, when the carbon fibers 310 are only arranged in one direction as shown in FIG. 3, the heat transfer efficiency in the direction in which the carbon fibers are arranged may be high, but the heat transfer efficiency in a direction perpendicular to the direction in which the carbon fibers are arranged may be low.

In other words, the heat dissipation efficiency in the first direction FD may be high because heat may be efficiently dissipated along the carbon fibers 310 arranged in the first direction FD, but the heat dissipation efficiency in the second direction SD may be low because heat transfer in the second direction SD is hindered by the resin 320 arranged between the carbon fibers 310.

In the following, a solution for increasing thermal efficiency in a direction in which the carbon fibers 310 are arranged and in a direction perpendicular thereto will be described with reference to the drawings.

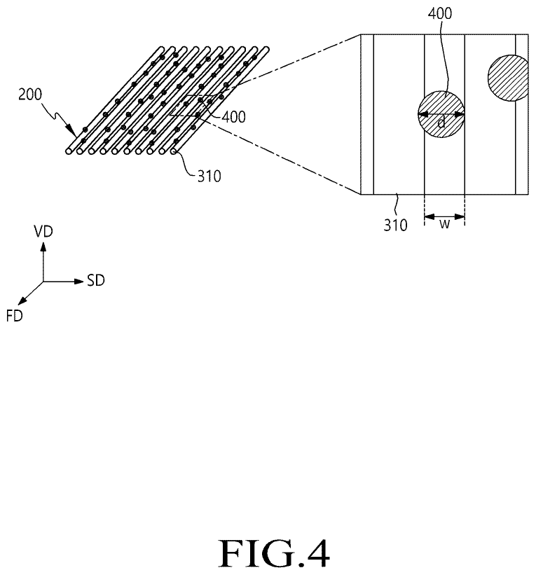

FIG. 4 illustrates another example of a 3D structure and a planar structure of the heat dissipation plate shown in FIG. 2.

In the following description, the features the same as or similar to those of the heat dissipation plate described above with reference to FIG. 3 are omitted or briefly given.

Referring to FIG. 4, a heat dissipation plate 200 may include carbon fiber 310 and at least one metal particle 400. The heat dissipation plate 200 may not include resin.

As an example, the carbon fibers 310 may be located on the same plane, or may be located on different planes (e.g., two or more planes). As an example, the arrangement of the carbon fibers 310 in the different planes may be the same or different. As an example, the carbon fibers 310 in the different planes may overlap with each other, may partially overlap with each other, or may not overlap with each other. As an example, the carbon fibers 310 may be arranged FD on the same plane in the first direction.

The diameter of each of the carbon fibers 310 may be from 5 μm to 7 μm, but is not limited thereto. As an example, the diameter of each of the carbon fibers 310 may be smaller than 5 μm or greater than 7 μm. As an example, the diameter of the carbon fibers 310 may be equal to each other or may be different from each other.

The length of the carbon fibers 310 in the first direction FD may correspond to the width of the display panel 130 in one direction. Here, the length of the carbon fibers 310 in the first direction FD corresponding to the width of the display panel 130 in one direction may mean that the length of the carbon fibers 310 in the first direction FD is equal or similar to the width of the display panel 130 in one direction (e.g., the first direction FD).

As an example, the length of the carbon fibers 310 in one direction included in the heat dissipation plate 200 may be greater than or equal to the length of the carbon fibers 310 in one direction described above with reference to FIG. 3.

Describing in detail, for the heat dissipation plate 200 shown in FIG. 3, the carbon fibers 310 must be impregnated with the resin 320 in order for the resin 320 to surround the carbon fibers 310. In this case, because increasing the length of the carbon fibers 310 may cause the carbon fibers 310 to break easily during the process of impregnating the carbon fibers 310 with the resin 320, it is desired that the carbon fibers 310 having a shorter length than the display panel 130 are arranged in succession.

However, the heat dissipation plate 200 shown in FIG. 4 does not include resin and thus does not require a process to impregnate the carbon fibers 310 with resin. Accordingly, the heat dissipation plate 200 may include longer carbon fibers 310 than the carbon fibers 310 shown in FIG. 3.

On the other hand, when short carbon fibers 310 are arranged in succession, there may be areas where the carbon fibers 310 overlap each other in sections where the carbon fibers 310 are connected, thereby lengthening a heat transfer path. Accordingly, the heat dissipation efficiency may be reduced compared to a case in which a single long carbon fiber 310 is used.

That is, the heat dissipation plate 200 including the longer carbon fibers 310, which contain no resin as shown in FIG. 4, may have better heat dissipation efficiency than the heat dissipation plate 200 shown in FIG. 3.

At least one metal particle 400 may be provided between the carbon fibers 310.

The metal particles 400 may include a metal having high thermal conductivity, such as nickel (Ni), silver (Ag), aluminum (Al), or copper (Cu). Embodiments are not limited thereto. As an example, a particle including a material have high thermal conductivity, such as graphite particle, other than metal may be provided between the carbon fibers 310.

As an example, the metal particles 400 may be provided on the surfaces of the carbon fibers 310. As an example, the metal particles 400 may be provided on the surfaces of the carbon fibers 310 by electroplating. As an example, the metal particles 400 may contact the surface of at least one of the carbon fibers 310. As an example, the metal particles 400 may contact the surfaces of both of adjacent the carbon fibers 310, without being limited thereto.

The shape of the metal particles 400 provided on the surfaces of the carbon fibers 310 may be the same or may be different from each other. As an example, the shape of the metal particles 400 provided on the surfaces of the carbon fibers 310 may vary depending on the conditions of the electroplating.

For example, the metal particles 400 provided on the surfaces of the carbon fibers 310 may have a spherical shape. In another example, the metal particles 400 may have a conical shape. As an example, the metal particles 400 provided on the surfaces of the carbon fibers 310 may have other shapes such as an oval shape, a polygonal shape, a rod shape, a cylindrical shape, or an irregular shape, without being limited thereto.

When the metal particles 400 have a spherical shape, the metal particles 400 may have a greater surface area to volume ratio than when the metal particles 400 may have a conical shape. Accordingly, a greater area of the metal particles 400 may be in contact with the carbon fibers 310.

In another example, the number, size, and uniformity of the metal particles 400 provided on the surfaces of the carbon fibers 310 may vary, for example, depending on the conditions of the electroplating.

For example, the lower the pH value of the electrolyte used for the electroplating, the more the metal particles 400 may be provided on the surfaces of the carbon fibers 310, and the more uniform the formed metal particles 400 may be.

The higher the temperature at which the electroplating is performed, the more the metal particles 400 may be provided on the surfaces of the carbon fibers 310, and the greater and more uniform the sizes of the metal particles 400 may be.

In another example, when electroplated at a higher current density, the metal particles 400 provided on the surfaces of the carbon fiber 310 may have greater sizes.

As shown in FIG. 4, the carbon fibers 310 may be physically connected by the metal particles 400.

The state of being physically connected means that metal particles 400 provided on the surface of one carbon fiber 310 are in contact with another adjacent carbon fiber 310, or that metal particles 400 are provided on both surfaces of two adjacent carbon fibers 310.

As an example, the distance w between the carbon fibers 310 may be smaller than the diameter d of the metal particles 400. As an example, the distance w between the carbon fibers 310 may be smaller than the diameter of the carbon fibers 310.

The metal particles 400 provided on the surface of one carbon fiber 310 may be in contact with other adjacent carbon fibers 310 or may also be provided on the surface of another adjacent carbon fiber 310 so that the carbon fibers 310 are physically connected. Accordingly, the carbon fibers 310 may remain in a unidirectional arrangement even when the resin is not provided between the carbon fibers 310.

The carbon fibers 310 are shown in FIG. 4 as forming a single layer, but this is illustrative for ease of description, and the carbon fibers 310 may be stacked in two or more layers.

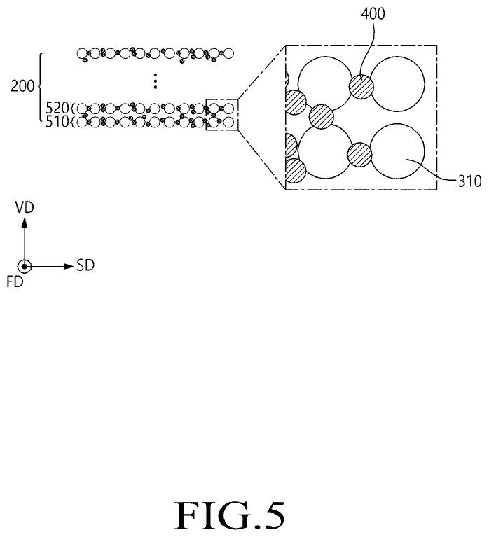

FIG. 5 illustrates an example of a cross-sectional structure of the heat dissipation plate shown in FIG. 4.

Referring to FIG. 5, the heat dissipation plate 200 may include carbon fibers 310 stacked in two or more layers. That is, the heat dissipation plate 200 may include a plurality of carbon fiber layers.

The heat dissipation plate 200 may include, but is not limited to, 20 to 30 carbon fiber layers. When the heat dissipation plate 200 includes 20 to 30 carbon fiber layers, the heat dissipation plate 200 may have a thickness of 100 μm to 150 μm. As an example, the heat dissipation plate 200 may include less than 20 or more than 30 carbon fiber layers, and/or may have a thickness smaller than 100 μm or greater than 150 μm.

For example, the heat dissipation plate 200 may include a first carbon fiber layer 510 and a second carbon fiber layer 520 arranged over the first carbon fiber layer 510.

Each of the first carbon fiber layer 510 and the second carbon fiber layer 520 may include a plurality of carbon fibers 310 arranged in the first direction FD, as shown in FIG. 4, and metal particles 400 provided on the surfaces of the plurality of carbon fibers 310.

The metal particles 400 provided on the surfaces of the carbon fibers 310 included in the first carbon fiber layer 510 may physically connect the plurality of carbon fibers 310 included in the first carbon fiber layer 510, and the metal particles 400 provided on the surfaces of the carbon fibers 310 included in the second carbon fiber layer 510 may physically connect the plurality of carbon fibers 310 included in the second carbon fiber layer 520.

As an example, at least some of the metal particles 400 provided on the surfaces of the carbon fibers 310 included in the first carbon fiber layer 510 may be in contact with at least one carbon fiber 310 included in the second carbon fiber layer 520, without being limited thereto. As another example, at least some of the metal particles 400 provided on the surfaces of the carbon fibers 310 included in the first carbon fiber layer 510 may not be in contact with the carbon fiber 310 included in the second carbon fiber layer 520.

In another example, a single metal particle 400 may be provided on both the surface of one carbon fiber 310 included in the first carbon fiber layer 510 and the surface of another carbon fiber 310 included in the second carbon fiber layer 520.

That is, the carbon fibers 310 included in the first carbon fiber layer 510 and the carbon fibers 310 included in the second carbon fiber layer 520 may be physically connected by the metal particles 400 provided on both the surface of carbon fibers of the first carbon fiber layer 510 and the surface of the second carbon fiber layer 520.

As described with reference to FIGS. 4 and 5, the heat dissipation plate 200 includes at least one metal particle 400 provided on the surfaces of the carbon fibers 310 adjacent to each other and physically connecting the adjacent carbon fibers 310, so that the shape of the unidirectionally arranged carbon fibers 310 may be maintained even when the resin is not included.

In addition, since the carbon fibers 310 are physically connected by the metal particles 400, i.e., the metal particles 400 provided on the surface of one carbon fiber 310 are also in contact with the surface of the adjacent carbon fiber 310, a heat transfer path in the second direction SD may be provided even when the carbon fibers 310 are arranged only in the first direction FD.

Specifically, heat generated by the display device may spread in the first direction FD, which is the direction in which the carbon fibers 310 are arranged, and at the same time, spread to the adjacent carbon fibers 310 located on the same plane through the metal particles 400 provided on the surfaces of the carbon fibers 310.

Thus, the heat dissipation efficiency may be increased not only in the direction in which the carbon fibers 310 are arranged, but also in the direction perpendicular thereto.

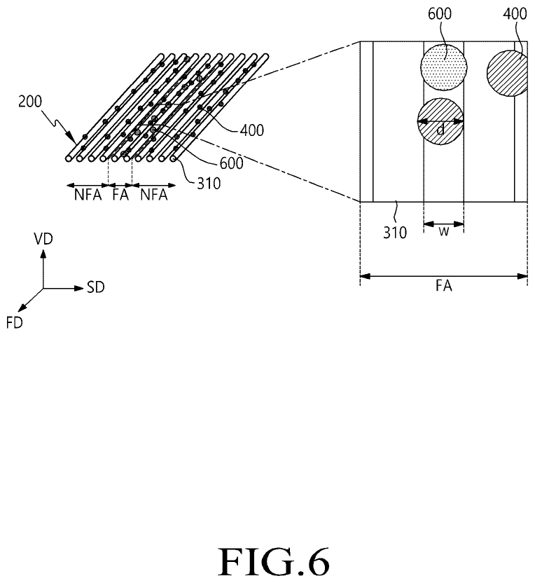

FIG. 6 illustrates an example of a cross-sectional structure of the heat dissipation plate shown in FIG. 2.

Referring to FIG. 6, the heat dissipation plate 200 may include a folding area FA and a non-folding area NFA.

The folding area FA may refer to an area where at least a portion of the display device including the heat dissipation plate 200 is bendable. The non-folding area NFA may refer to an area where at least a portion of the display device including the heat dissipation plate 200 is not bendable.

The heat dissipation plate 200 may include at least one folding area FA.

As an example, microcapsules 600 may be disposed between the carbon fibers 310 disposed in an area overlapping the folding area FA. As an example, the microcapsules 600 may be not even in an area overlapping the folding area FA. As an example, the microcapsules 600 may be further disposed in the non-folding area NFA.

The microcapsules 600 may be, but are not necessarily limited to, a urea-formaldehyde resin.

As an example, when a crack is formed around the area where the microcapsules 600 are disposed, a portion of the microcapsules 600 may disintegrate to fill the crack.

When the heat dissipation plate 200 is folded about the folding axis in the first direction FD in the folding area FA, cracks may be formed on the surfaces of some of the carbon fibers 310 located in the folding area FA. As an example, the folding axis may be parallel with the carbon fibers 310, without being limited thereto.

At this time, the microcapsules 600 located between the carbon fibers 310 may partially disintegrate and fill the cracks, thereby providing durability in the area where the heat dissipation plate 200 is folded.

In addition, even when the heat dissipation plate 200 including the folding area FA includes two or more stacked layers of the carbon fibers 310, as shown in FIG. 5, the layers of the carbon fibers 310 located in the area overlapping the folding area FA may be stacked on each other after the microcapsules 600 are disposed thereon to reduce or prevent cracks that would otherwise be formed on the layers of the carbon fibers 310, thereby providing the durability of the heat dissipation plate 200.

Another structure of the heat dissipation plate 200 that may increase the heat dissipation efficiency of the display device is described below.

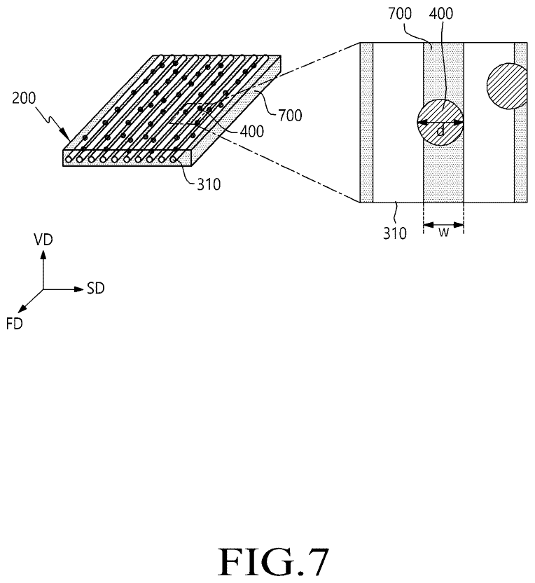

FIG. 7 illustrates another example of a 3D structure and a planar structure of the heat dissipation plate shown in FIG. 2.

The heat dissipation plate 200 shown in FIG. 7 is substantially the same as the heat dissipation plate 200 shown in FIG. 4, except that resin 700 is further included, and thereof repetitive description thereof is omitted or briefly given.

Referring to FIG. 7, the heat dissipation plate 200 may include carbon fibers 310, at least one metal particle 400, and resin 700.

The resin 700 may be, but is not limited to, an epoxy-based resin or a urethane-based resin.

The resin 700 may surround the plurality of carbon fibers 310 and the metal particles 400 provided on the surfaces of the carbon fibers 310. As an example, the resin 700 may fully surround the plurality of carbon fibers 310 and the metal particles 400 provided on the surfaces of the carbon fibers 310, or may expose a portion of at least one of the plurality of carbon fibers 310 or a portion of the metal particles 400.

The resin 700 may hold the carbon fibers 310 in place so that the arrangement of the carbon fibers 310 arranged in one direction is not disturbed.

As shown in FIG. 7, the width of the resin 700 disposed between the carbon fibers 310 may be equal to the distance w between adjacent carbon fibers 310. In addition, the width of the resin 700 disposed between the carbon fibers 310 may be smaller than the diameter of the metal particles 400.

The carbon fibers 310 are shown in FIG. 7 as forming a single layer, but this is illustrative for ease of description, and the carbon fibers 310 may be stacked in two or more layers.

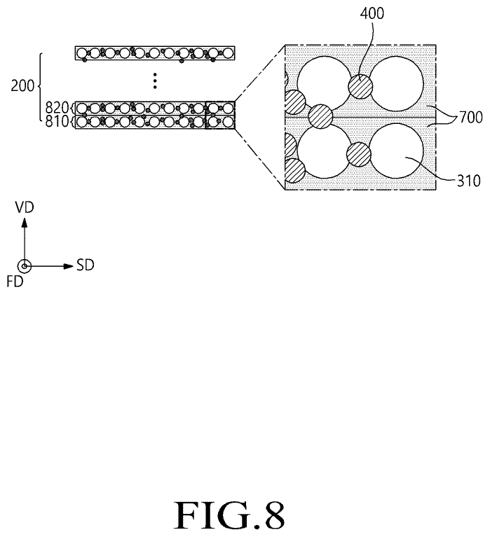

FIG. 8 illustrates an example of a cross-sectional structure of the heat dissipation plate shown in FIG. 7.

The heat dissipation plate 200 shown in FIG. 8 is substantially the same as the heat dissipation plate 200 shown in FIG. 5, except that resin 700 is further included, and thereof repetitive description thereof is omitted or briefly given.

Referring to FIG. 8, the heat dissipation plate 200 may include carbon fibers 310 stacked in two or more layers. That is, the heat dissipation plate 200 may include a plurality of carbon fiber layers.

The heat dissipation plate 200 may include, but is not limited to, 20 to 30 layers of carbon fibers. When the heat dissipation plate 200 includes 20 to 30 carbon fiber layers, the thickness of the heat dissipation plate 200 may be from 100 μm to 150μ m.

For example, the heat dissipation plate 200 may include a first carbon fiber layer 810 and a second carbon fiber layer 820 arranged over the first carbon fiber layer 810.

As shown in FIG. 8, each of the first carbon fiber layer 810 and the second carbon fiber layer 820 may include a plurality of carbon fibers 310 arranged in the first direction FD, metal particles 400 provided on the surfaces of the plurality of carbon fibers 310, and resin 700 surrounding the carbon fibers 310 and the metal particles 400.

The resin 700 included in the first carbon fiber layer 810 may be in contact with the resin 700 included in the second carbon fiber layer 700. That is, the top surface of the resin 700 surrounding the carbon fibers 310 of the first carbon fiber layer 810 may be in contact with the bottom surface of the resin 700 surrounding the carbon fibers 310 of the second carbon fiber layer 820.

The resin 700 included in the first carbon fiber layer 810 may fill between the carbon fibers 310 included in the first carbon fiber layer 810. As described above, the width of the resin 700 located between the carbon fibers 310 is smaller than the diameter of the metal particles 400, so that the carbon fibers 310 included in the first carbon fiber layer 810 may be physically connected even when the first carbon fiber layer 810 includes the resin 700.

Similarly, the resin 700 included in the second carbon fiber layer 820 may fill between the carbon fibers 310 included in the second carbon fiber layer 820, and the width of the resin 700 located between the carbon fibers 310 is smaller than the diameter of the metal particles 400, so that the carbon fibers 310 included in the second carbon fiber layer 820 may be physically connected even when the second carbon fiber layer 820 includes the resin 700.

In addition, as an example, the thickness of the resin 700 disposed between the carbon fibers 310 included in the first carbon fiber layer 810 and the carbon fibers 310 included in the second carbon fiber layer 820 may be smaller than the diameter of the metal particles 400. Therefore, the carbon fibers 310 in each layer may be physically connected even when each of the first carbon fiber layer 810 and the second carbon fiber layer 820 include the resin 700. Embodiments are not limited thereto. As an example, the thickness of the resin 700 disposed between the carbon fibers 310 included in the first carbon fiber layer 810 and the carbon fibers 310 included in the second carbon fiber layer 820 may be equal to or greater than the diameter of the metal particles 400. As an example, the carbon fibers 310 in each layer may be not physically connected with each other.

As described with reference to FIGS. 7 and 8, when the heat dissipation plate 200 includes the resin 700, the carbon fibers 310 arranged in one direction may be held in shape so as not to be dislodged.

In addition, even when the heat dissipation plate 200 includes the resin 700, the width or thickness of the resin 700 disposed between the carbon fibers 310 is smaller than the diameter of the metal particles 400, and thus heat may be transferred through the metal particles 400 not only in the first direction FD, which is the direction in which the carbon fibers 310 are arranged, but also in the second direction SD perpendicular to the first direction FD, thereby increasing the heat dissipation efficiency in the second direction SD.

In addition, the resin 700 is adhesive as will be described later, and thus the heat dissipation plate 200 may be attached to the back plate 120 without a separate adhesive layer, thereby advantageously reducing the thickness of the display device.

When the heat dissipation plate 200 described with reference to FIGS. 7 and 8 has a folding area FA as shown in FIG. 6, microcapsules may be further disposed between the carbon fibers 310 located in an area overlapping the folding area FA.

In addition, even when the carbon fibers 310 are stacked in two or more layers, microcapsules may be disposed between the carbon fibers 310 located in each layer.

Here, the microcapsules may be surrounded by the resin 700.

In a case where the microcapsules are disposed between the carbon fibers 310, when a crack is formed near the surfaces of the carbon fibers 310, some of the microcapsules may disintegrate and fill the crack, thereby providing the durability of the heat dissipation plate 200.

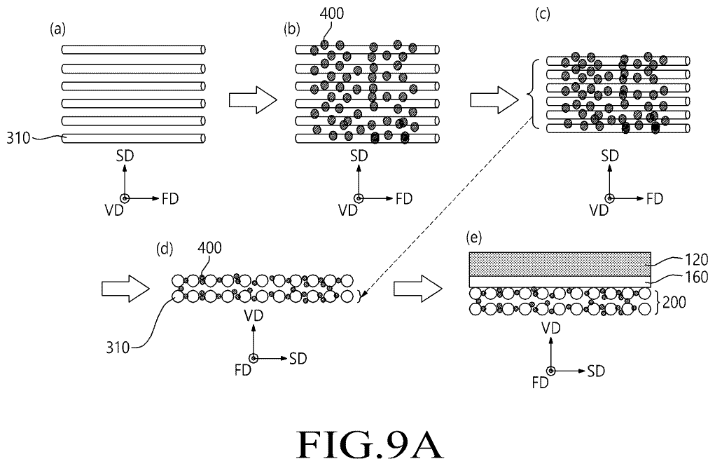

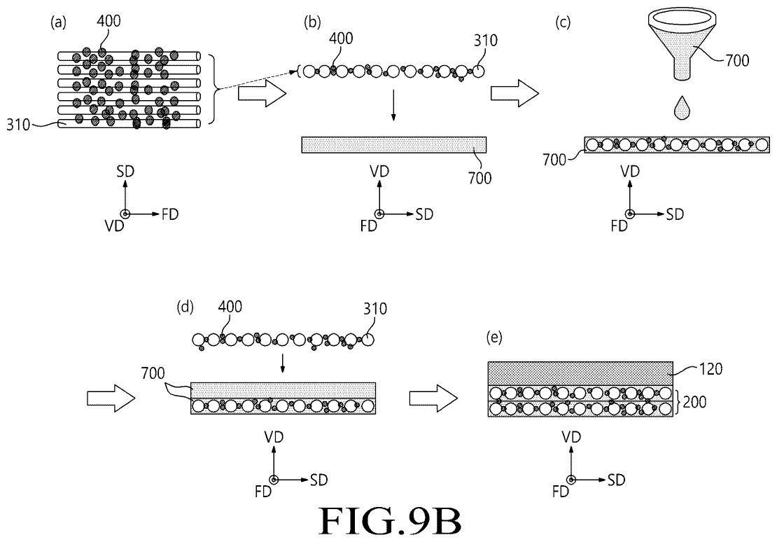

In the following, a method of manufacturing a heat dissipation plate 200 including carbon fibers 310 and metal particles 400 is described. FIG. 9A illustrates an example of a method of fabricating the heat dissipation plate shown in FIGS. 4 and 5, and FIG. 9B illustrates an example of a method of fabricating the heat dissipation plate shown in FIGS. 7 and 8.

Referring to (a) of FIG. 9A, the carbon fibers 310 arranged in one direction may be subjected to dipping, curing (or heat treatment), and carbonizing processes to fix the arrangement thereof. The dipping and curing processes may be performed at 175° C. for 6 hours, and the carbonization process may be performed at 2400° C., but these are not intended to be limiting.

Referring to (b) of FIG. 9A, metal particles 400 may be electroplated on the carbon fibers 310 the arrangement of which is fixed.

The metal used for electroplating may include, but is not limited to, at least one of nickel (Ni), silver (Ag), copper (Cu), or aluminum (Al).

The metal particles 400 may be formed on the surface of at least one carbon fiber 310, for example, by electroplating.

The metal particles 400 formed on the surfaces of the carbon fibers 310 may have a spherical shape. As an example, after being formed, the metal particles 400 formed on the surface of one carbon fiber 310 may contact or may not contact another adjacent carbon fiber 310, or the metal particles 400 may be formed on the surfaces of both or only one of two adjacent carbon fibers 310.

Referring to (c) of FIG. 9A, the carbon fibers 310 electroplated with the metal particles 400 may be directed and then pressed.

The pressing may be performed by, for example, hot pressing at 100° C. for 1 hour.

The pressing may be performed in a direction perpendicular to a direction in which the carbon fibers 310 are arranged. For example, when the carbon fibers 310 are arranged in the first direction FD, as shown in (c) of FIG. 9A, the carbon fibers 310 may be pressed in the third direction VD or the second direction SD, or in both the third direction VD and the second direction SD.

When the carbon fibers 310 are pressed, the distance between the carbon fibers 310 may decrease.

As described above with reference to FIGS. 4 to 8, the distance between the pressed carbon fibers 310 may be smaller than the diameter of the metal particles 400.

Thus, the carbon fibers 310 may be physically connected by the metal particles 400. That is, the metal particles 400 formed on the surface of one carbon fiber 310 may contact another adjacent carbon fiber 310, or the metal particles 400 may be formed on the surfaces of both two adjacent carbon fibers 310.

Referring to (d) of FIG. 9A, the carbon fiber 310 may be stacked in two or more layers.

(d) and (e) of FIG. 9A illustrate, but are not necessarily limited to, a structure in which the carbon fibers 310 included in the heat dissipation plate 200 are stacked in two layers, and the carbon fibers 310 may be a single layer or may be stacked in three or more layers. When the carbon fibers 310 included in the heat dissipation plate 200 form a single layer, the operation of (d) of FIG. 9A may be omitted.

When the carbon fibers 310 are stacked in two layers as shown in (d), the carbon fibers 310 of the second layer may be arranged over the carbon fibers 310 and the metal particles 400 arranged in the first layer after being electroplated and pressed by the operations of (a) to (c) above.

Thereafter, the carbon fibers 310 stacked in two layers may be pressed once again. The pressing may be performed, for example, by hot pressing.

The pressing may physically connect the carbon fibers 310 located in the first layer and the carbon fibers 310 located in the second layer by the metal particles 400 located between the first layer and the second layer.

Referring to (e) of FIG. 9A, the heat dissipation plate 200 including at least one carbon fiber 310 plated with the metal particles 400 may be attached to the back plate 120, for example, by an adhesive layer 160.

In the heat dissipation plate 200 formed by the above-described operations, since the carbon fibers 310 are physically connected by the metal particles 400 formed on the carbon fibers 310 by the above-described operations, heat transfer paths may be formed in the direction in which the carbon fibers 310 are arranged as well as in the direction perpendicular to the direction in which the carbon fibers 310 are arranged, thereby increasing the heat dissipation efficiency of the display device.

Referring to (a) of FIG. 9B, the metal particles 400 may be electroplated on the carbon fibers 310 arranged in one direction.

The carbon fibers 310 electroplated with the metal particles 400 may be pressed in at least one direction.

The process of electroplating the metal particles 400 on the carbon fibers 310 arranged in one direction and the process of pressing the electroplated carbon fibers 310 may be performed in substantially the same manner as described above with reference to (a) to (c) of FIG. 9A.

Referring to (b) of FIG. 9B, the pressed carbon fibers 310 may be arranged over resin 700.

The resin 700 may be, but is not limited to, an epoxy-based resin or a urethane-based resin.

When the carbon fibers 310 are arranged on the resin 700, the resin 700 may surround the electroplated carbon fibers 310. In this case, since the resin 700 is provided between the pressed carbon fibers 310, the width of the resin 700 between the carbon fibers 310 may be smaller than the diameter of the metal particles 400.

Referring to (c) of FIG. 9B, a second portion of resin 700 may further be applied on a layer of the carbon fibers 310 and the resin 700.

The second resin 700 may be applied at substantially the same height as the resin 700 in the layer of the carbon fibers 310 and the resin 700 described with reference to (b) of FIG. 9B in the third direction VD, but is not limited thereto.

Referring to (d) of FIG. 9B, a second layer of electroplated carbon fibers 310 may further be arranged over the resin 700 (more particularly, the second resin 700). Here, the electroplated carbon fibers 310 may be the pressed carbon fibers 310 as described with reference to (b) of FIG. 9B.

In (c) of FIG. 9B, the applied second resin 700 may cover the layer of the electroplated carbon fibers 310.

The second resin 700 may surround the electroplated carbon fibers 310.

Referring to (e) of FIG. 9B, the carbon fibers 310 surrounded by the resin 700 may be stacked in two or more layers. (e) of FIG. 9B illustrates a structure in which the carbon fibers 310 included in the heat dissipation plate 200 and the resin 700 surrounding the carbon fibers 310 are stacked in two layers, it is not necessarily limited thereto, and the carbon fibers 310 may be a single layer or may be stacked in three or more layers. When the carbon fibers 310 included in the heat dissipation plate 200 form a single layer, the operation of (d) of FIG. 9B may be omitted.

When the layers of the carbon fibers 310 and the resin 700 are stacked alternately, one layer at a time, friction that may occur between the layers of the carbon fiber 310 may be reduced, thereby reducing or preventing damage to the surfaces of the carbon fibers 310 or separation of the metal particles 400 from the carbon fibers 310 during the process of pressing and stacking the carbon fibers 310.

The carbon fibers 310 and the resin 700 stacked in two layers may be pressed once again. The pressing may be performed by, for example, hot pressing.

By the pressing, the carbon fibers 310 located in the first layer and the carbon fibers 310 located in the second layer may be physically connected by the metal particles 400 located between the first and second layers.

As an example, the thickness of the resin 700 located between the carbon fibers 310 located in the first layer and the carbon fibers 310 located in the second layer may be smaller than the diameter of the metal particles 400.

Referring to (e) of FIG. 9B, the heat dissipation plate 200 including at least one carbon fiber 310 plated with the metal particles 400 and the resin 700 may be attached to the back plate 120 without a separate adhesive layer. That is, the resin 700 is adhesive, and thus the top surface of the resin 700 surrounding the carbon fiber 310 in the second layer may contact the bottom surface of the back plate 120.

In the heat dissipation plate 200 formed by the above-described operations, even when the resin 700 is included, the carbon fibers 310 may be physically connected by the metal particles 400 formed on the carbon fibers 310 to form heat transfer paths not only in the direction in which the carbon fibers 310 are arranged but also in the direction perpendicular to the direction in which the carbon fibers 310 are arranged, thereby increasing the heat dissipation efficiency of the display device. In addition, since the heat dissipation plate 200 includes the resin 700, the heat dissipation plate 200 may be directly attached to the bottom surface of the back plate 120 without a separate adhesive layer, thereby reducing the thickness of the display device, reducing or preventing surface damage to the carbon fibers 310, and reducing or preventing the metal particles 400 from being detached from the carbon fibers 310.

The above-described embodiments of the present disclosure are briefly reviewed as follows.

Embodiments may provide a display device including: a display panel; and a heat dissipation plate disposed under the display panel and including a plurality of carbon fibers arranged in one direction and at least one metal particle, wherein the metal particle is provided on a surface of at least one first carbon fiber among the plurality of carbon fibers and in contact with at least one second carbon fiber adjacent to the at least one first carbon fiber.

In the display device according to embodiments, the distance between the plurality of carbon fibers may be smaller than the diameter of the carbon fibers.

In the display device according to embodiments, the metal particle may have a spherical shape.

In the display device according to embodiments, the display device may further include resin disposed between the plurality of carbon fibers.

In the display device according to embodiments, the thickness of a portion of the resin located between adjacent carbon fibers among the plurality of carbon fibers may be equal to or smaller than the diameter of the metal particle.

In the display device according to embodiments, the display may further include a back plate disposed between the display panel and the heat dissipation plate, wherein at least a portion of the resin is in contact with a back surface of the back plate.

In the display device according to embodiments, the length of each of the plurality of carbon fibers in one direction may correspond to the width of the display panel in one direction.

In the display device according to embodiments, the metal particle may be electroplated on the surface of the at least one first carbon fiber.

In the display device according to embodiments, the metal particle may include at least one among nickel (Ni), aluminum (Al), silver (Ag), or copper (Cu).

In the display device according to embodiments, the carbon fibers are poly-acrylonitrile PAN carbon fibers or pitch-based carbon fibers.

Embodiments may provide a heat dissipation plate including: a first carbon fiber layer including a plurality of carbon fibers arranged in one direction; a second carbon fiber layer located over the first carbon fiber layer, and including carbon fibers arranged in the direction in which the carbon fibers included in the first carbon fiber layer are arranged; a first metal particle disposed in the first carbon fiber layer, disposed on a surface of at least one first carbon fiber included in the first carbon fiber layer, and being in contact with at least one second carbon fiber included in the first carbon fiber layer and adjacent to the at least one first carbon fiber; and a second metal particle disposed in the second carbon fiber layer, disposed on a surface of at least one first carbon fiber included in the second carbon fiber layer, and being in contact with at least one second carbon fiber included in the second carbon fiber layer and adjacent to the at least one first carbon fiber.

In the heat dissipation plate according to embodiments, the distance between the carbon fibers included in the first carbon fiber layer or the second carbon fiber layer may be smaller than the diameter of the carbon fibers.

In the heat dissipation plate according to embodiments, each of the first metal particle and the second metal particle may have a spherical shape.

In the heat dissipation plate according to embodiments, the heat dissipation plate may further include resin disposed between the carbon fibers included in the first carbon fiber layer, between the carbon fibers included in the second carbon fiber layer, and between the first carbon fiber layer and the second carbon fiber layer.

In the heat dissipation plate according to embodiments, the length of each of the plurality of carbon fibers in one direction may correspond to the width of the display panel in one direction.

In the heat dissipation plate according to embodiments, the first and second metal particles may be electroplated on the surface of the first carbon fibers included in the first and second carbon fiber layers, respectively.

Embodiments may provide a method of manufacturing a display device, the method including: electroplating metal on a plurality of first carbon fibers arranged in one direction and located on a single plane; pressing the plurality of electroplated first carbon fibers; arranging a plurality of electroplated second carbon fibers over the plurality of first carbon fibers, the second carbon fibers being arranged in the direction in which the plurality of first carbon fibers are arranged; pressing the plurality of first carbon fibers and the plurality of second carbon fibers; and attaching the plurality of pressed first carbon fibers and the plurality of pressed second carbon fibers to a back side of a back plate.

In the method according to embodiments, the method may further include arranging the plurality of first carbon fibers over resin between pressing the plurality of first carbon fibers and arranging the plurality of second carbon fibers over the plurality of first carbon fibers.

It will be apparent to those skilled in the art that various modifications and variations can be made in the display device, the heat dissipation plate, and the method of fabricating the display device of the present disclosure without departing from the technical idea or scope of the disclosure. Thus, it is intended that the present disclosure cover the modifications and variations of this disclosure provided they come within the scope of the appended claims and their equivalents.

1. A display device, comprising:
a display panel; and
a heat dissipation plate disposed under the display panel and comprising a plurality of carbon fibers extended in one direction and at least one particle, wherein the particle is provided on a surface of one first carbon fiber among the plurality of carbon fibers and in contact with one second carbon fiber adjacent to the one first carbon fiber.

2. The display device of claim 1, wherein the particle is a metal particle.

3. The display device of claim 1, wherein a distance between the plurality of carbon fibers is smaller than a diameter of the carbon fibers.

4. The display device of claim 1, further comprising resin disposed between the plurality of carbon fibers,
wherein a width of a portion of the resin located between adjacent carbon fibers among the plurality of carbon fibers is equal to or smaller than a diameter of the particle.

5. The display device of claim 4, further comprising a back plate disposed between the display panel and the dissipation plate,
wherein at least a portion of the resin is in contact with a back surface of the back plate.

6. The display device of claim 1, wherein a length of each of the plurality of carbon fibers in the one direction corresponds to a width of the display panel in the one direction.

7. The display device of claim 1, wherein the particle is electroplated on the surface of the one first carbon fiber.

8. The display device of claim 1, wherein the particle comprises at least one among nickel (Ni), aluminum (Al), silver (Ag), or copper (Cu).

9. The display device of claim 1, wherein the heat dissipation plate further comprises microcapsules between the carbon fibers,
wherein microcapsules are disposed between the carbon fibers disposed in an area overlapping a folding area of the display device.

10. The display device of claim 1, wherein the surface of at least one of the plurality of carbon fibers comprises a crack filled with urea-formaldehyde resin.

11. A heat dissipation plate comprising:
a first carbon fiber layer comprising a plurality of carbon fibers extended in one direction;
a second carbon fiber layer located over the first carbon fiber layer, and comprising a plurality of carbon fibers extended in the one direction;
a first particle disposed in the first carbon fiber layer, disposed on a surface of one first carbon fiber included in the first carbon fiber layer, and being in contact with one second carbon fiber included in the first carbon fiber layer and adjacent to the one first carbon fiber; and
a second particle disposed in the second carbon fiber layer, disposed on a surface of one first carbon fiber included in the second carbon fiber layer, and being in contact with one second carbon fiber included in the second carbon fiber layer and adjacent to the one first carbon fiber included in the second carbon fiber layer.

12. The heat dissipation plate of claim 11, wherein the first particle and the second particle are metal particles.

13. The heat dissipation plate of claim 11, wherein the distance between the carbon fibers included in the first carbon fiber layer or the second carbon fiber layer is smaller than the diameter of the carbon fibers.

14. The heat dissipation plate of claim 11, further comprising resin disposed between the carbon fibers included in the first carbon fiber layer, between the carbon fibers included in the second carbon fiber layer, and between the first carbon fiber layer and the second carbon fiber layer.

15. The heat dissipation plate of claim 11, wherein a length of each of the plurality of carbon fibers in the one direction corresponds to a width of the display panel in the one direction.

16. The heat dissipation plate of claim 11, wherein the first particle is electroplated on the surface of the first carbon fiber included in the first carbon fiber layer, and the second particle is electroplated on the surface of the one carbon fiber included in the second carbon fiber layer.

17. The heat dissipation plate of claim 11, wherein at least one particle is in contact with at least one carbon fiber included in the first carbon fiber layer and at least one carbon fiber included in the second carbon fiber layer.

18. A display device comprising:
a display panel; and
the heat dissipation plate according to claim 11, disposed under the display panel.

19. A method of manufacturing a display device, the method comprising:
electroplating metal on a plurality of first carbon fibers extended in a first direction and located on a single plane;
pressing the plurality of electroplated first carbon fibers in a second direction perpendicular to the first direction in the single plane;
arranging a plurality of electroplated second carbon fibers over the plurality of first carbon fibers, the second carbon fibers being extended in the first direction;
pressing the plurality of first carbon fibers and the plurality of second carbon fibers in a third direction perpendicular to the first direction and the second direction; and
attaching the plurality of pressed first carbon fibers and the plurality of pressed second carbon fibers to a back side of a back plate.

20. The method of claim 19, further comprising arranging the plurality of first carbon fibers over resin between pressing the plurality of first carbon fibers and arranging the plurality of second carbon fibers over the plurality of first carbon fibers.
